(19) United States
(12) Patent Application Publication
(10) Pub. No.: US 2026/0254131 A1
(43) Pub. Date: Aug. 27, 2026

(54) ANTENNA FILTER UNITS FOR BASE STATION ANTENNAS AND RELATED RADIO ADAPTOR BOARDS

(71) Applicant: Outdoor Wireless Networks LLC, Claremont, NC (US)

(72) Inventors: Ligang Wu, Suzhou (CN); Chengcheng Tang, Richardson, TX (US); Giuseppe Resnati, Milan (IT); Fusheng Lv, Suzhou (CN); Fan He, Suzhou (CN); Zhanming Zhang, Suzhou (CN)

(21) Appl. No.: 18/879,425

(22) PCT Filed: Apr. 27, 2023
(86) PCT No.: PCT/US2023/020101

§ 371 Date: Dec. 27, 2024

(30) Foreign Application Priority Data
Jul. 13, 2022 (IT) 102022000014683

(51) Int. Cl. H01Q 21/00; H01Q 1/24; H01Q 21/28

(52) U.S. Cl. CPC H01Q 21/0025; H01Q 1/246; H01Q 21/0075; H01Q 21/0087; H01Q 21/28

(57) ABSTRACT

Active antenna units for base station antennas are provided that include a radio housing, an adaptor board, radiating elements that extend forward of feed boards and a cavity filter assembly with a plurality of cavity filter units. The adaptor board can define a rear cover for the cavity filter assembly and front cover for the radio. The adaptor board has a plurality of radio ports and signal traces that connect to other ports. Coaxial cable assemblies can provide alternate signal paths and/or strip printed circuit boards can provide alternate signal paths. The coaxial cable assemblies can include shielding covers and supports.

### BACKGROUND

The present invention generally relates to radio communications and, more particularly, to base station antennas for cellular communications systems.

Cellular communications systems are well known in the art. In a cellular communications system, a geographic area is divided into a series of regions or “cells” that are served by respective macrocell base stations. Each macrocell base station may include one or more base station antennas that are configured to provide two-way radio frequency (“RF”) communications with subscribers that are within the cell served by the base station. In many cases, each base station is divided into “sectors.” In one common configuration, a hexagonally-shaped cell is divided into three 120° sectors in the azimuth plane, and each sector is served by one or more macrocell base station antennas that generate radiation patterns (referred to herein as “antenna beams”) that have an azimuth Half Power Beamwidth (HPBW) of approximately 65°. Typically, the base station antennas are mounted on a tower or other raised structure, with the antenna beams that are generated by the base station antennas directed outwardly.

FIG. 1 is an exploded perspective view of a conventional active antenna unit 11. The active antenna unit 11 may be used as a standalone base station antenna or may be mounted to a passive base station antenna to provide active antenna functionality to the passive base station antenna. Referring to FIG. 1, the active antenna unit 11 includes a radome 11r, radiating elements 12 projecting forward from feedboards 14, a reflector 15, a calibration board 17, cavity filters 20, a radio cover 22 and radio 25r with a heat sink body 25. The reflector 15, cavity filters 20 with shielding covers 20c and the radio cover 22 can each be formed of metal defining respective separate ground planes.

### SUMMARY

Pursuant to embodiments of the invention, active antenna units (antenna filter units) for base station antennas are provided that include adaptor boards that are configured to interface with different radios having different RF port configurations and with a common cavity filter of the active antenna unit.

Embodiments of the invention are directed to an active antenna unit that includes a radio with a plurality of radio ports and an adaptor board with a plurality of radio frequency (RF) ports that communicate with the radio ports and signal traces that connect the RF ports to other ports of the active antenna unit.

The signal traces can connect the RF ports to respective filter cavity ports.

Some of the signal traces can be longer than others of the signal traces.

The RF ports can be aligned in a vertical or horizontal direction.

The RF ports can be laterally staggered and can be arranged to serially alter over a length of the adaptor board between a first lateral position and a second lateral position.

At least some of the signal traces can be angled laterally across the adaptor board, parallel to each other.

The active antenna unit can further include at least one coaxial cable extending along and/or across the adaptor board between first and second ports corresponding to one of the RF ports and one of the other ports of the active antenna unit.

The adaptor board can include a primary printed circuit board and a strip printed circuit board coupled to the primary printed circuit board. The primary printed circuit board has a larger surface area than the strip printed circuit board and the strip printed circuit board can include a signal trace.

The strip printed circuit board can have a dielectric substrate that can have a lower dielectric constant material than a dielectric substrate of the primary printed circuit board.

A first subset of the RF ports can be connected to feed boards of radiating elements of the active antenna unit.

The adaptor board can have a strip printed circuit board with at least one signal trace thereon that can be configured to angle laterally across a length dimension of the adaptor board.

The signal trace of the one or more strip printed circuit boards can connect to an aligned signal trace on the adaptor board.

The active antenna unit can include cavity filters residing behind feed boards of radiating elements of the active antenna unit. The adaptor board can define a front cover for the radio and can also define a rear cover for the cavity filters.

The adaptor board can be attached to the cavity filters.

The active antenna unit can include a module sub-assembly with cavity filters, each cavity filter can have a respective cavity filter unit housing. The sub-assembly can include feed boards coupled to radiating elements residing in front of the cavity filter housing.

The adaptor board can be provided as a plurality of different adaptor boards, each with a different signal trace configuration and different radio port locations and a common footprint. Each of the plurality of different adaptor boards can be interchangeably, serially attachable to the active antenna unit to thereby allow the active antenna unit to connect and interface with different radios with different radio port configurations.

The active antenna unit can further include cavity filters coupled to the adaptor board. The adaptor board can have tuning elements configured to tune the cavity filters.

The adaptor board can be arranged to define a low pass filter function.

The active antenna unit can further include cavity filters with twistable tuning elements. The adaptor board can have a sheet metal layer that is coupled to a ground plane side of the adaptor board and that extends over at least one access aperture of respective cavity filters and over at least one twistable tuning element in each of the respective cavity filters.

The active antenna unit can further include a radome mounted forwardly of a radio housing holding the radio and a plurality of feed boards with a plurality of radiating elements projecting forward of the plurality of feed boards residing between the adaptor board and the radome.

The plurality of radiating elements can include a massive multiple input multiple output (MIMO) antenna array.

Other embodiments are directed to an assembly for an active antenna unit. The assembly includes: a radio board coupled to radio circuitry of a radio; an adaptor board coupled to the radio board and comprising a plurality of spaced apart apertures; and a cavity filter assembly coupled to the adaptor board and comprising a plurality of cavity filters with a respective tuning element in a respective cavity thereof. At least one aperture of the spaced apart apertures of the adaptor board resides behind and over each cavity of the cavity filters whereby capacitance of the tuning element is adjustable through the at least one aperture.

The adaptor board can have radio port connections and couples a radio and the cavity filters.

The adaptor board can have a primary printed circuit board with opposing front and rear primary surfaces. At least one of the front primary surface comprises a layer of metal can define a tuning layer for the cavity filters.

Yet other embodiments are directed to a strip printed circuit board for an antenna that includes an elongate printed circuit board comprising at least one linear signal transmission path. The elongate printed circuit board has a width dimension and a length dimension and the length dimension is at least five times larger than the width dimension.

The elongate printed circuit board can have a first ground layer, a second ground layer and a dielectric layer therebetween. The at least one linear signal transmission path can be provided in the dielectric layer and can terminate at opposing end portions at a respective metal coated or plated aperture extending through the elongate printed circuit board.

The elongate printed circuit board can have a low DF substrate. In operation, RF signal is transmitted along the at least one linear signal transmission path to thereby provide a low loss transmission path.

Still other aspects are directed to a coaxial cable assembly that includes a coaxial cable comprising an outer jacket and a center conductor; and a support member with a semi-circular outer wall providing an open channel that extends about a portion of the coaxial cable. The support member can further include a first end portion that extends in a first direction and an opposing second end portion having a circular collar that extends in a second direction that is orthogonal to the first end portion. The semi-circular outer wall terminates at the circular collar. First and second pins of the support member project outward from the circular collar wall on diametrically opposed sides of the center conductor and the first and second pins and the center conductor are configured to be soldered to a common side of a printed circuit board.

The first and second segments can be configured to define a head space between the printed circuit board and the outer jacket of the coaxial cable.

The support member can be metal.

Still other embodiments are directed to a coaxial cable assembly that includes a coaxial cable comprising an outer jacket, a dielectric insulator and a center conductor; and a cover comprising an outer wall with axially spaced apart first and second end portions and that at least partially surrounds an open channel that extends about a first portion of the coaxial cable with the center conductor exposed and with the outer jacket removed and a second portion of the coaxial cable that is adjacent the first portion. The second portion has center conductor and the dielectric insulator intact but the outer jacket removed. The first end portion of the cover is open and receives the coaxial cable and the second end portion has a closed end.

The outer wall of the cover can have a “U” shape with a pair of free ends on opposing sides of the open channel.

The cover can have a height that corresponds to an outer diameter of the coaxial cable.

The coaxial cable assembly can further include a printed circuit board. The free ends of the outer wall of the cover can face and be coupled to an electrical ground provided on a primary surface of the printed circuit board. The center conductor can exit the cover at a 90-degree bend from the first end portion of the cover and can be soldered to an opposing primary surface of the printed circuit board to connect to an RF signal connection thereby providing improved RF performance shielding.

Still other aspects are directed to an adaptor board assembly that includes a first printed circuit board with a dielectric layer and first and second electrical ground layers on opposing sides of the dielectric layer. The first printed circuit board has a width and length dimension. The first printed circuit board has a signal trace in the dielectric layer that extends along the length dimension and that extends only along outer facing ends of the first printed circuit board from a soldering pad. The adaptor board assembly also includes a second printed circuit board with a dielectric layer and first and second electrical ground layers on opposing sides of the dielectric layer. The second printed circuit board has a width and length dimension. The second printed circuit board includes a signal trace in the dielectric layer that extends along the length dimension and terminates at a soldering pad aligned with the soldering pad of the first printed circuit board. At least one of the width and length dimension of the second printed circuit board is less than that of the first printed circuit board. The second printed circuit board is coupled to the first printed circuit board and the signal trace of the second printed circuit board has a longer extent than the signal trace of the first printed circuit board to thereby provide a low loss signal path.

The second printed circuit board can have a DF that is less than a DF of the first printed circuit board, optionally the second printed circuit board has a DF<0.0010. Optionally, the first printed circuit board has a DF that is in a range of about 0.0020-0.0030.

The first printed circuit board can have a plurality of spaced apart RF ports configured to couple to RF ports of a radio of an active antenna unit or other antenna.

The adaptor board assembly can further include a connector pin extending through aligned apertures in the first and second printed circuit boards at the soldering pads thereof.

The first and second printed circuit boards can be laminated to define an integral structure.

The second printed circuit board can be configured to face a radio side of a radio of an antenna and the first printed circuit board can define a cover for a cavity filter of the antenna.

The adaptor board can have different signal paths with separate cables providing some of the signal paths and other of the signal paths implemented as trace signal paths on the adaptor board.

The adaptor board can have one or more elongate, strip printed circuit boards with respective one or more traces that are coupled to a larger printed circuit board of the adaptor board to provide one or more of the signal paths.

The strip printed circuit boards can be formed of a lower dielectric constant material than the larger printed circuit board in order to reduce dielectric losses.

The adaptor board can have connectors/filter input ports, a plurality of filter output ports, a plurality of RF antenna ports and a plurality of traces that connect defined ports.

The adaptor board can be defined by at least one printed circuit board.

The adaptor board can define a front cover for the radio and a rear cover for the cavity filters.

Different adaptor boards can be interchangeably, serially attached to an active antenna module and connect different radio configurations to filters of the active antenna unit.

The active antenna unit can include an array of radiating elements that can optionally be provided as patch radiating elements.

The adaptor board can have tuning ports that can be configured to adjust capacitive coupling between element of one or more respective cavity filters.

The adaptor board can provide a low pass filter function.

A thin sheet metal layer may be coupled to a ground plane side of the adaptor board over at least one access aperture of respective cavity filters and over at least one twistable tuning element in each of the respective cavity filters.

### BRIEF DESCRIPTION OF THE DRAWINGS

FIG. 1 is a front, side perspective, partially exploded view of a prior art active antenna unit.

FIG. 2 is a front, side perspective, partially exploded view of an active antenna unit according to embodiments of the present invention.

FIG. 3 is a front, side, partially exploded view of a portion of the active antenna unit shown in FIG. 2.

FIG. 4 is a front, side perspective assembled view of the components shown in FIG. 3.

FIG. 5 is a side view of the assembled components shown in FIG. 4.

FIG. 6 is a front, side perspective, partially exploded view of an active antenna unit according to additional embodiments of the present invention.

FIG. 7 is a front, side, partially exploded view of a portion of the active antenna unit shown in FIG. 6.

FIG. 8 is a front, side assembled view of the components shown in FIG. 7.

FIG. 9 is a side view of the assembled components shown in FIG. 8.

FIGS. 10-12 are front, side, partially exploded views of example components of active antenna units according to embodiments of the present invention that have adaptor boards with different signal path configurations.

FIG. 13 is a is a rear, side perspective, exploded view of a cavity filter assembly according to embodiments of the present invention.

FIG. 14 is a rear, side perspective, assembled view of the components shown in FIG. 13.

FIG. 15 is a rear, side perspective view of the housing and feed board components shown in FIG. 13.

FIG. 16 is a rear, side perspective view of the housing and resonator frame components shown in FIG. 13.

FIG. 17A is a greatly enlarged schematic illustration of an example cavity filter with a twistable tuning element that cooperates with a tuning surface according to embodiments of the present invention.

FIG. 17B is a greatly enlarged schematic illustration of an example twistable tuning element for a cavity filter according to embodiments of the present invention.

FIG. 17C is a side perspective view of another embodiment of an adaptor board comprising a printed circuit board with resonators and/or a low pass filter (LPF) according to embodiments of the present invention.

FIG. 18A is a schematic illustration of a deflectable tuning element provided by a metal layer or an adaptor board according to embodiments of the present invention.

FIG. 18B is a schematic illustration of apertures provided by a metal layer or an adaptor board for tuning adjustment of the cavity filters according to embodiments of the present invention.

FIG. 19 is a side perspective view of an example coaxial cable assembly providing a signal transmission path according to embodiments of the present invention.

FIGS. 20A-20B are enlarged side perspective views of a portion of a support for the coaxial cable shown in FIG. 19.

FIG. 21 is an enlarged side perspective view of a connection end portion of the coaxial cable assembly shown in FIG. 19.

FIG. 22 is a partially transparent view of an end portion of the coaxial cable assembly shown in FIG. 19.

FIG. 23 is a side perspective view of another example coaxial cable assembly providing a signal transmission path according to embodiments of the present invention.

FIGS. 24A and 24B are side, perspective views of the shield at the end portions of the coaxial cable shown in FIG. 23.

FIGS. 25A-25C are lateral sectional views of example profiles of an outer wall of the shield at the end portions of the coaxial cable shown in FIG. 23 according to embodiments of the present invention.

FIG. 26 is an enlarged side perspective view of a connection end portion of the coaxial cable assembly shown in FIG. 23.

FIG. 27 is a partially transparent view of a portion of the coaxial cable assembly shown in FIG. 23.

FIG. 28 is a side perspective view of an example signal trace configuration comprising a strip printed circuit board according to embodiments of the present invention.

FIG. 29 is an enlarged view of an end portion of the signal trace configuration shown in FIG. 28.

FIG. 30 is an enlarged side sectional view of a portion of the example signal trace configuration shown in FIG. 28.

FIG. 31A is a side perspective view of a portion of an example active antenna unit showing the example signal trace configuration of FIG. 28 used with an adaptor board according to embodiments of the present invention.

FIG. 31B is a side perspective view of a portion of an example active antenna unit showing an example coaxial cable assembly, optionally such as that shown in FIG. 19 or 23, for example, providing a signal path for an adaptor board according to embodiments of the present invention.

FIG. 32 is a side schematic view of an antenna, optionally an active antenna unit, with the adaptor board provided in front of the cavity filters according to embodiments of the present invention.

FIG. 33 is a rear perspective view of a base station antenna comprising the active antenna unit held at least partially external to the passive antenna housing according to embodiments of the present invention.

FIG. 34 is a simplified lateral cross-section view of a base station antenna with the active antenna unit held inside the base station antenna according to embodiments of the present invention.

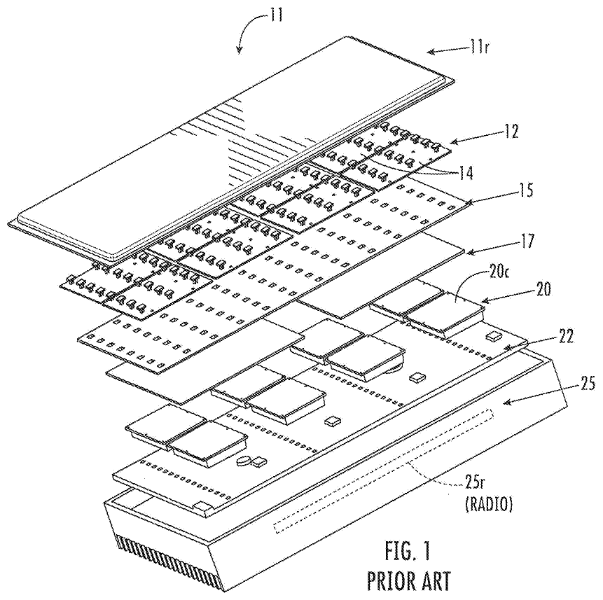

### DETAILED DESCRIPTION

The demand for cellular communications capacity has been increasing at a high rate. As a result, the number of base station antennas has proliferated in recent years. Base station antennas are both relatively large and heavy and, as noted above, are typically mounted on antenna towers. Due to the wind loading on the antennas and the weight of the antennas and associated radios, cabling and the like, antenna towers must be built to support significant loads. This increases the cost of the antenna towers.

In the description that follows, active antenna units for base station antennas and the components thereof are described using terms that assume that the base station antennas are mounted for use on a tower with the longitudinal axis of the antenna extending along a vertical (or near vertical) axis and the front surface of the antenna mounted opposite the tower or other mounting structure pointing toward the coverage area for the antenna.

Embodiments of the present invention will now be discussed in greater detail with reference to the attached figures.

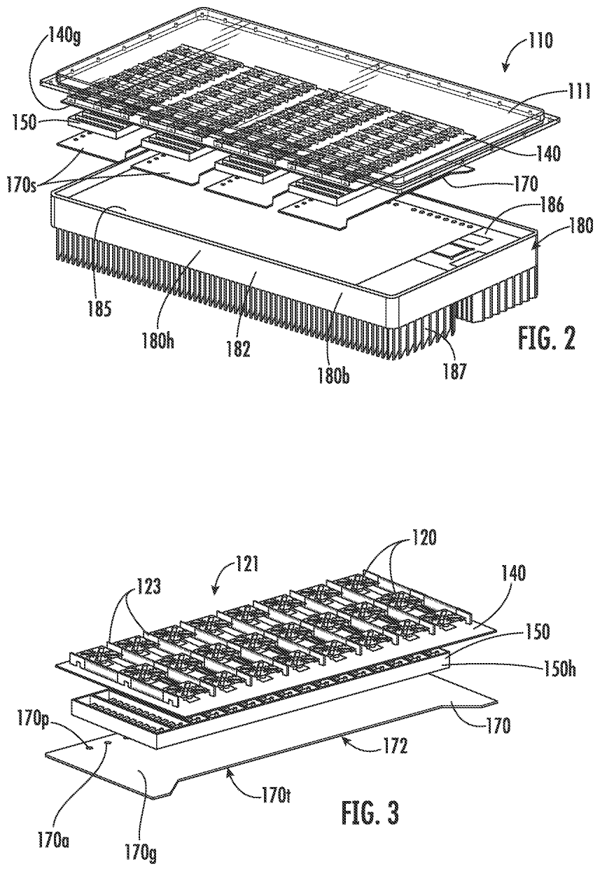

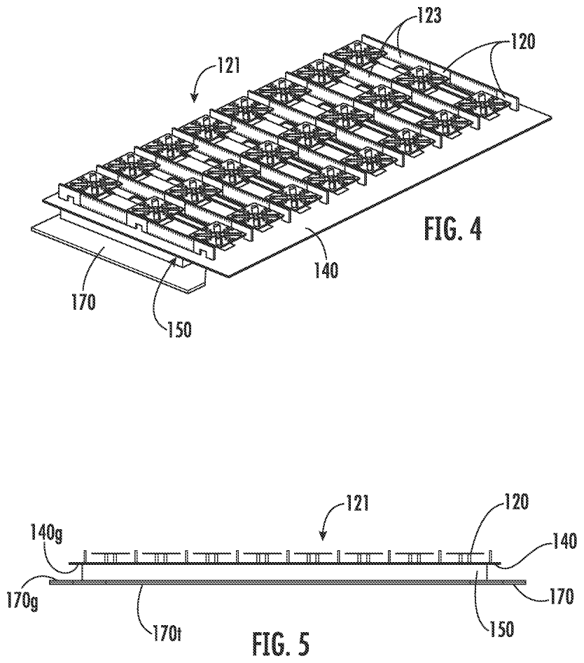

With reference to FIGS. 2-5, an example active antenna unit 110 is shown. It is noted that the term “active antenna unit” is interchangeably referred to herein as an “active antenna module” or an “antenna filter unit”. The active antenna unit 110 can include a radome 111, radiating elements 120, one or more feed boards 140, cavity filters 150, an adaptor board 170 and a radio 180 comprising radio circuitry 182. The radio circuitry 182 can be provided using at least one radio board 185. The cavity filters 150 can be provided with a frame and/or housing 150h providing a plurality of cavity filters 150.

Active antenna modules may be deployed as standalone base station antennas or may be deployed in base station antennas configured as larger antenna structures that include additional active antenna modules and/or conventional “passive” antenna arrays that may be connected to radios that are external to the antenna structures.

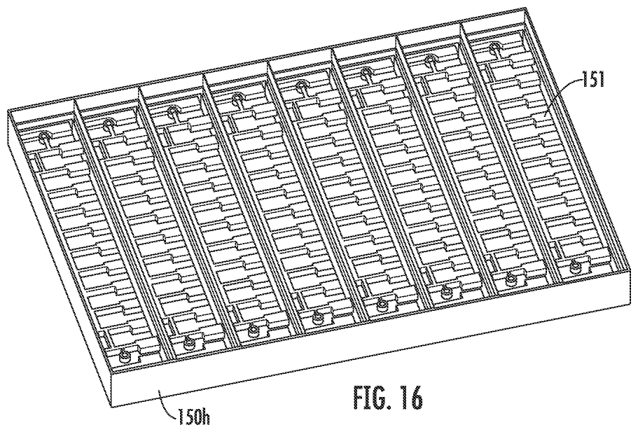

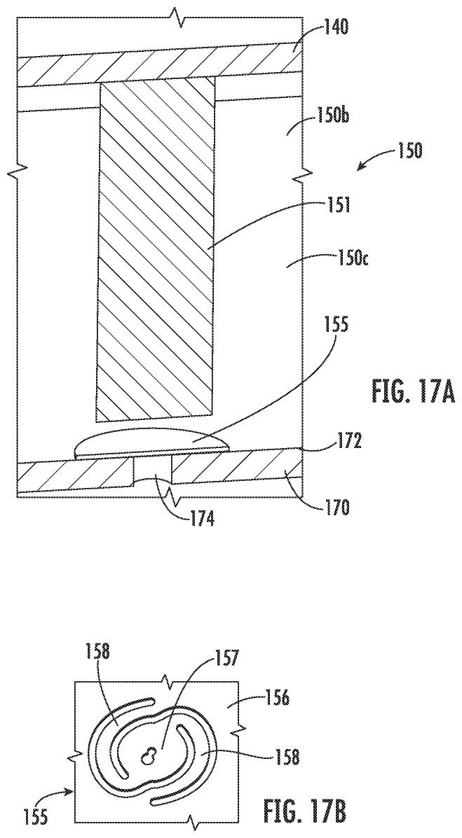

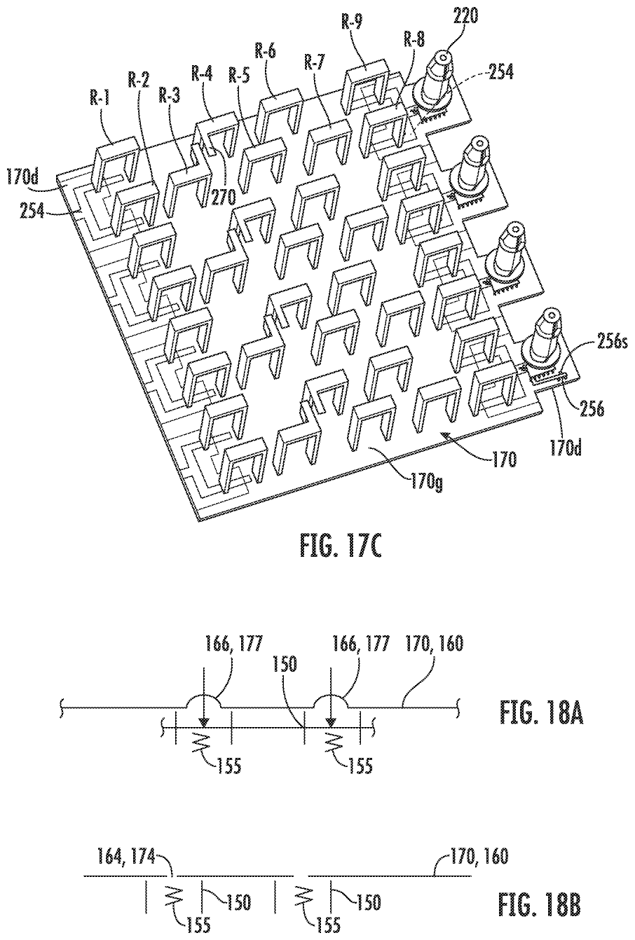

The cavity filters 150 can be resonant cavity filters as is well known to those of skill in the art. The cavity filters 150 can have unit bodies 150b that have an internal cavity 150c with tuning elements 155 (FIGS. 17, 18). The cavity filters 150 and/or the adaptor board 170 can define a ground plane for the radiating elements 120. The cavity filters 150 will be discussed further below.

The adaptor board 170 can define a front cover for the radio 180 and can couple to the radio housing 180h. The radio housing 180h can comprise a heat sink 187. The adaptor board 170 can reside in a recess 186 provided at a front of the radio body 180b. The adaptor board 170 can define a rear cover of the cavity filters 150.

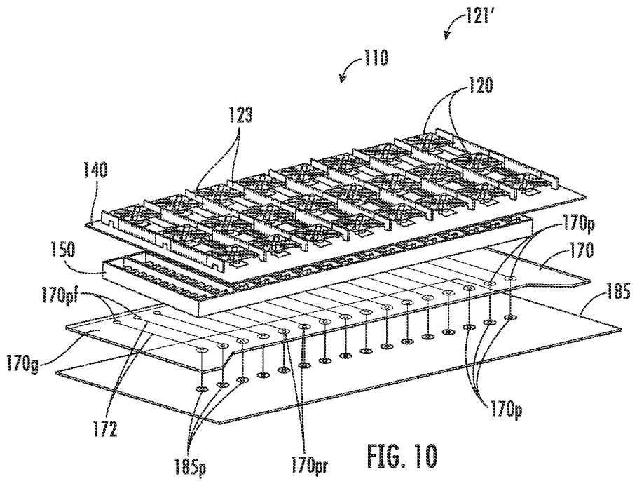

The adaptor board 170 of the active antenna unit 110 can directly couple to the radio board 185 or to RF connectors of the radio without requiring a radio board 185. The radio board 185, where used, can comprise a plurality of radio ports 185p and the adaptor board 170 can comprise a plurality of ports 170p, at least some of which can align with and couple to the radio ports 185p (FIGS. 10-12). The adaptor board 170 can also comprise a plurality of signal traces 172 (FIGS. 10-12).

FIG. 2 shows that the adaptor board 170 can be provided as a plurality of cooperating board segments 170s, one each that resides behind one of the unit bodies 150b of the cavity filters 150.

The adaptor board 170 can be provided as at least one printed circuit board with a plurality of ports 170p and signal traces 172. The ports 170p can comprise input and output ports for signal paths between the radio 180 and the cavity filters 150. The ports 170p can include an RF port 170a on an antenna side.

The radiating elements 120 can be arranged as columns of radiating elements as shown. The radiating elements 120 can be configured as massive Multiple Input, Multiple Output (mMIMO) arrays. The radiating elements 120 can be provided as patch radiating elements, in some embodiments. The radiating elements 120 can be provided as cross dipole radiating elements in other embodiments. Isolation fences 123 may be provided between adjacent rows and/or columns of radiating elements 120.

The feed boards 140 can have an electrical ground surface, typically formed of copper. The adaptor board 170 can have an electrical ground surface 170g, typically formed of copper. The feed boards 140 can be provided as cooperating sets of feed boards 140 that define a top cover of the cavity filters 150. The adaptor board 170 can also define a back cover of the cavity filters 150. The ground surface 140g of the feed boards 140 can define a reflector for the radiating element 120 so that no separate (e.g., aluminum) reflector is required.

In some embodiments, the back surface 170b of the adaptor board 170 can comprise one or more tuning features 170t for the cavity filters 150.

The active antenna unit 110 can have a module sub-assembly 121 comprising the feed boards 140 with the radiating elements 120, the cavity filters 150 and the adaptor board 170 that can electrically connect together by a feeding pin(s), for example, without requiring standalone connectors such as blindmate connectors. The feed boards 140, cavity filters 150 and adaptor board 170 can all be soldered together at one time. The integrated, compact configuration can provide a low weight, low cost, and/or low profile configuration.

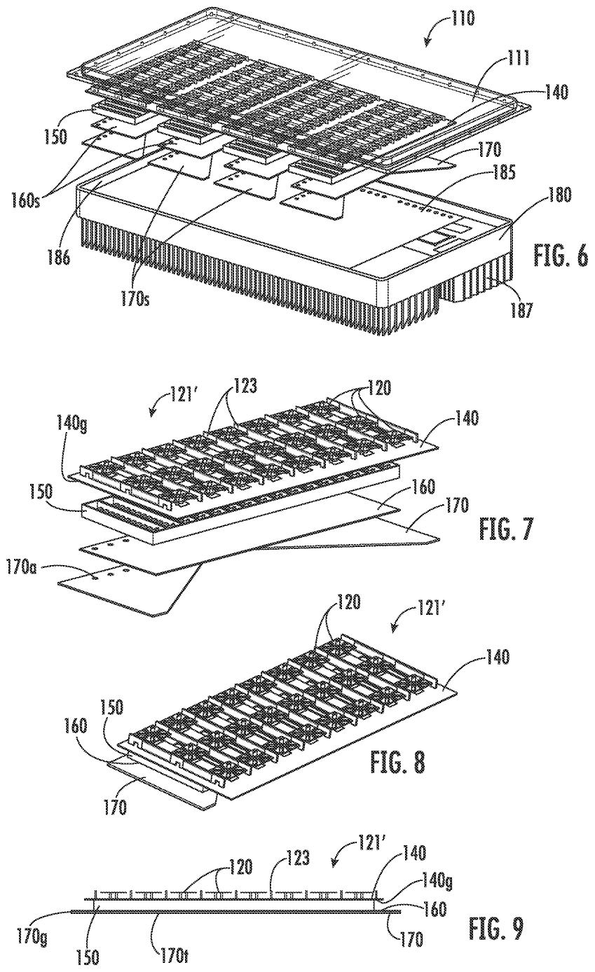

Turning now to FIGS. 6-9, in some embodiments the active antenna unit 110 can further comprise a metal sheet cover 160 between the adaptor board 170 and the cavity filters 150. The sheet metal cover 160 defines the rear cover of the cavity filters 150 instead of the adaptor board 170. The adaptor board 170 is coupled to the metal sheet cover 160 and resides between the metal sheet cover 160 and the radio 180. The ground surface 140g of the feed boards 140 defining a cover for the cavity filters 150 can also provide a reflector for the radiating elements 120.

The metal sheet cover 160 can be configured to provide a tuning element for the cavity filters 150. The metal sheet cover 160 (FIG. 6, 18A), where used, or the adaptor board 170 (FIG. 2, 18A) can be configured with movable metal segments 166, 177, aligned over a cavity filter with internal tuning element 155, such as a protrusion or indentation that can be deflected inward or outward to tune of the cavity filters 150. Alternatively, the metal sheet cover 160 (FIG. 6, 18B), were used, or the adaptor board 170 (FIG. 2, 18B) can comprise tuning apertures 164, 174 (FIG. 18B) that allows a rod or pin to be inserted into the cavity filter 150 to tune the cavity filter 150.

The cavity filters 150 can cooperate with the feed boards 140 and/or the adaptor board 170 to define a reflector thus eliminating the need for a separate reflector behind the feed boards 140 and in front of the cavity filters 150 as in conventional active antenna units.

The cavity filters 150 can electrically couple to a metal surface of the adaptor board 170 to thereby define a common electrical ground plane.

Different radios can have ports in different locations and embodiment of the present invention provide adaptor boards 170 that can couple the ports of different radios to a common antenna filter unit.

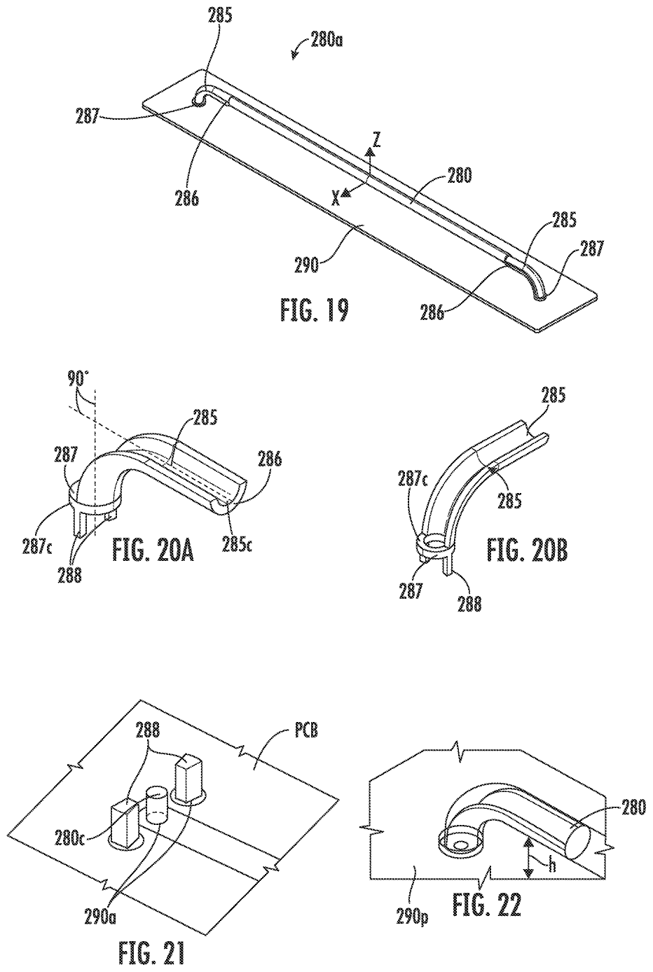

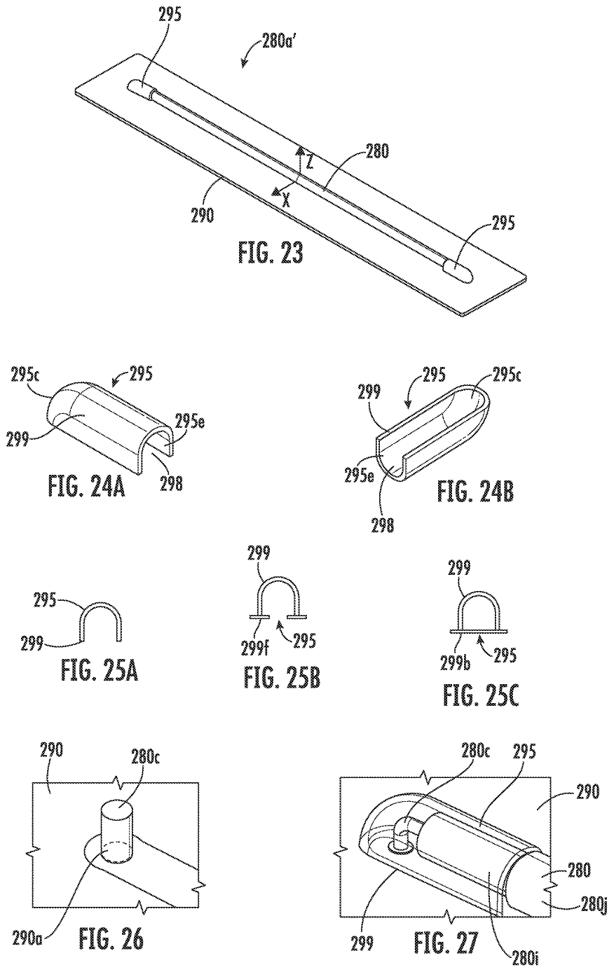

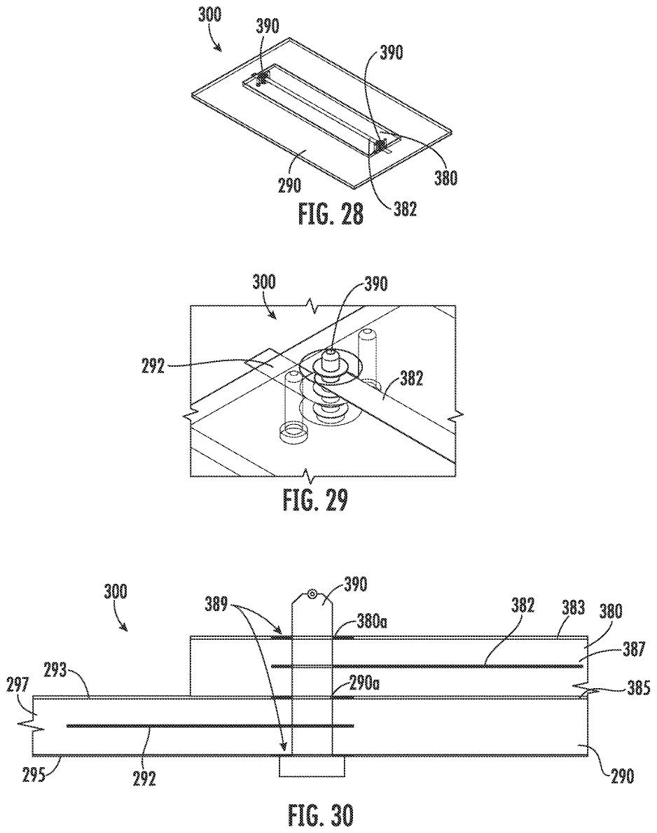

Turning now to FIGS. 10-12, adaptor boards 170 with different port 170p and signal trace 172 configurations are shown (the adaptor boards 170 are shown partially transparent to illustrate the signal traces 172 facing the radio 180). The signal paths and/or traces 172 can connect the radio ports 170pr to filter ports 170pf. The adaptor boards 170 can be provided as a multiple layer printed circuit board with at least one dielectric layer sandwiched by two adjacent metal or metallized primary surfaces (FIGS. 28-30 show three metal layers comprising two parallel ground layers and two dielectric layers). One outer primary surface can be an electrical ground plane 170g (typically of copper) and can be oriented to face the cavity filters 150. In the embodiments shown in FIGS. 10-12, the other outer primary surface comprises signal paths provided at least partially by signal traces 172, typically oriented to face the radio 180. Optionally, a subset of the signal paths can be provided by coaxial cables 280 (FIGS. 19, 23) and/or strip printed circuit boards 380 (FIG. 28) as will be discussed further below.

The signal traces 172 can be parallel and some may have the same length between input and output ports 170p. FIG. 10 shows horizontally oriented signal traces 172 having a common length. FIG. 11 shows a staggered arrangement of ports 170p where adjacent signal traces 172 have different lengths and a first port 170p₁ is at a first position and a second adjacent port 170p₂ is at a second position that is laterally spaced apart from the first position.

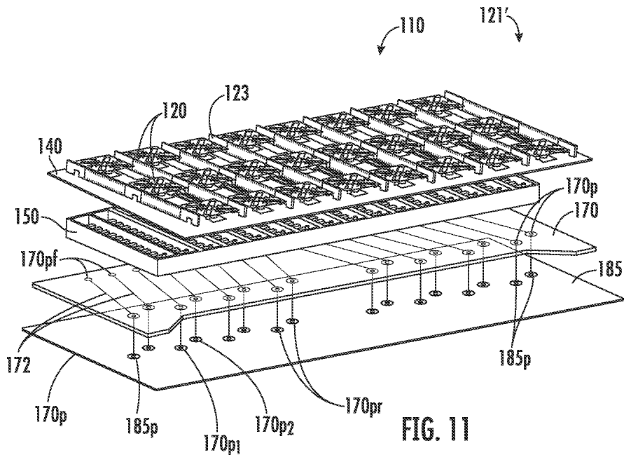

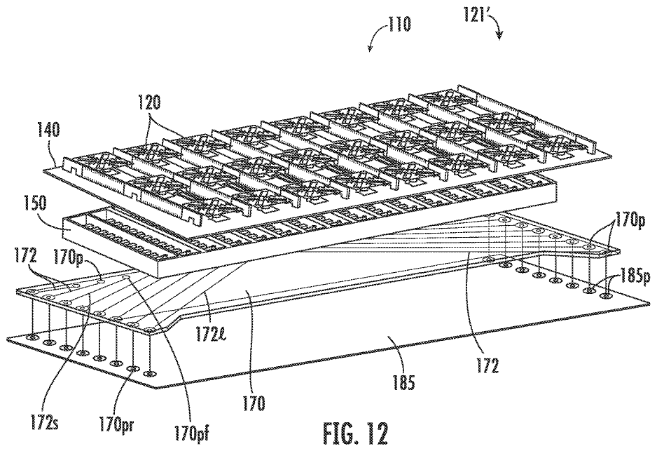

FIG. 12 shows ports 170p at top and bottom end portions of the adaptor board 170 that are coupled to ports 185p on the radio board, typically by connector features of the ports 170p, 185p. The ports 170p, 185p can include some that are arranged vertically along one side.

The adaptor board 170 can comprise signal traces 172 angled inward from the top and bottom ports 170p to provide long traces 172l that decrease in size across the board 170 to shorter traces 172s. As shown, at least some of the traces 172 are parallel and have an angle of inclination that is between 15-60 degrees from horizontal.

Where the lengths of signal traces 172 are different, phase variations that result from the different length transmission paths can be compensated for in, for example, the radio 180.

The adaptor board 170 can be provided with different configurations of signal trace configurations 172 to correspond with different radios 180 having different radio port locations and a common footprint to interchangeably couple to a module sub-assembly 221 of the active antenna unit 110 to thereby allow the module sub-assembly 221 to accept different radios 180.

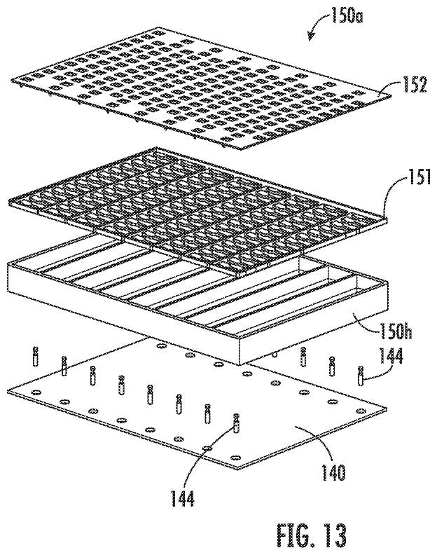

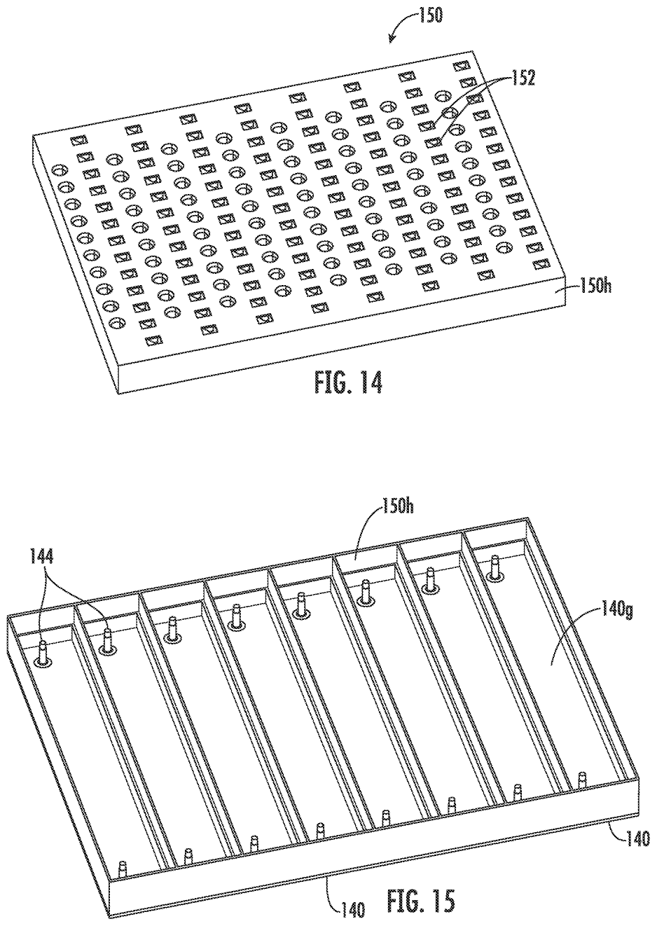

Turning now to FIGS. 13-16, an example cavity filter assembly 150a is shown. As shown, the cavity filter assembly 150a comprises a tuning lid or cover 152, a resonator frame 151, a housing 150h, feed boards 140 and conductors 144 electrically connecting the cavity filters 150 with the feed boards 140. Through holes for the conductors 144 can be plated to reduce insertion loss driven by the dielectric. The active antenna unit 110 can comprise a plurality of the cavity filter assemblies 150a, typically in a range of 4-12, more typically 4-8, shown as four (4) in FIGS. 2 and 6. The housing 150h can have an internal lip and the resonator plate 151 rests on, is typically soldered to, the lip. The two front resonator and tuning plates/frames 151, 152, respectively, can both go into the housing 150h from the front side.

As discussed above, the adapter boards according to embodiments of the present invention may be used to form a cover of the filter (e.g., the bottom cover). Moreover, the feed boards of the antenna array may be used to form the other cover of the filter (e.g., the top cover). While this reduces the part count and weight of the antenna, it creates a potential difficulty as the tuning elements for the filters are typically mounted in the top or bottom covers of the filter. Pursuant to further embodiments of the present invention, tuning elements may be mounted in or on the adapter boards disclosed herein so that the filter scan be tuned. This is shown with reference to FIGS. 17A-17B.

Turning first to FIG. 17A, an enlarged view of a portion of a cavity filter 150 is shown. A feed board 140 acts as one cover of the filter 150 and the adaptor board 170 acts as the other cover of the filter. As shown in FIG. 17A, the filter 150 includes a plurality of cavities 150c (only one cavity is shown). A resonator 151 is mounted in each cavity to extend from the feed board 140. A twistable tuning element 155 is formed within a small piece of sheet metal 156. The small piece of sheet metal 156 is soldered to the side of the adapter board 170 that faces the filter 150. A tuning aperture 174 is provided in the adaptor board 170, and the small piece of metal 156 covers the tuning aperture 174. A rod or pin can be inserted through the tuning aperture 174 to displace a coupling element of the twistable tuning element (see discussion below) toward the resonator 151 in order to tune the filter 150.

Referring to FIG. 17B, each twistable tuning element 155 may be formed by cutting curved slots into the piece of sheet metal 156. These slots define a central coupling element 157 and a pair of arms 158 in the depicted embodiment. The coupling element 157 may be displaced axially into the filter cavity 150c and may move along an axis that is generally perpendicular to a plane defined by the wall or plate. As such, the tuning element may be designed to remain centered over an underlying element (e.g., a resonator) in the cavity filter 150, regardless of the degree to which the twistable tuning element 155 is moved as part of the tuning process. The tuning element may rotate or “twist” in the plane that is parallel to the wall or plate as it is moved, which facilitates maintaining its position along the axis.

The twistable tuning element 155 can have any suitable shape, including, but not limited to, spiral, triangular, square, rectangular, circular, semi-circular and the like. Additional discussions of twistable tuning elements can be found in U.S. Pat. No. 10,050,323, the contents of which are incorporated by reference as if recited in full herein. Moreover, while twistable tuning elements are shown in FIGS. 17A-17B, it will be appreciated that in other embodiments conventional tuning screws or pins may instead be mounted on the adapter board 170 and be configured so that they can be inserted an adjustable distance into the cavity filter 150 through the respective tuning apertures in order to tune the filter 150.

Unlike conventional cavity filters 150, no external solid metal cover or metal sticker is required and the capsule can be soldered to the adaptor board 170.

Turning to FIG. 17C, it is also noted that other functionality can be added to the adaptor board 170. Resonators “R” may be mounted (e.g., soldered) on a primary surface of the adaptor board 170. In such embodiments, the tuning elements may be mounted on the feed boards 140 instead of on the adapter board 170 so that the tuning elements may be adjacent the distal end of each resonator. In some embodiments, the adjacent resonators R-3, R-4 may have respective laterally-protruding portions 270 that are capacitively coupled to each other. The adjacent resonators R-3, R-4 can thus be capacitively coupled to each other. Others of the resonators R-C may be capacitively coupled to each other by laterally-overlapping leg portions. Because the resonator R-1 may not be capacitively coupled to the adjacent resonator R-2, these two resonators R may be coupled to each other by an RF transmission line 254. For example, the transmission line 254 may be on a dielectric substrate 170d of the adaptor board 170, and one end of each of the resonators R-1, R-2 may be on and coupled to the transmission line 254. An opposite end of each of the resonators R-1, R-2 may be on and coupled to a ground plane 170g that is on the adaptor board 170. The adjacent resonators R-8, R-9 may likewise be coupled to each other by another RF transmission line 254 that is on the adaptor board 170. Moreover, both (i.e., opposite) ends of each of the five resonators R-3 through R-7 may be on and coupled to the ground plane 170g. The ground plane 170g may comprise, for example, copper.

In some embodiments, at least one low-pass filter (“LPF”) 256 is provided on a primary surface of the adaptor board 170 and coupled to a respective one of the cavity filters 150. In example embodiments, the LPF 256 may be implemented as a metal trace (e.g., of a microstrip line) having one or more metal stubs 256s protruding therefrom on a dielectric substrate 170d of the adaptor board 170 when provided as a printed circuit board.

The LPF 256 can be embedded in adaptor board (stripline type) and can be configured to provide rejection at a higher band.

The LPF 256 may be configured to cut off spurious/parasitic resonances (e.g., frequencies above 3.8 GHz). Moreover, as shown in FIG. 17C, the LPF 256 may be adjacent and/or coupled to a connector 220. In other embodiments, the LPF 256 may be on a front or rear primary surface and/or may be outside of a conductive housing. As an example, the LPF 256 may be adjacent and/or coupled to a connection (e.g., a plated through hole (“PTH”)) between a cavity filter 150 and radiating elements 120 or between the radio 180 and the cavity filter 150.

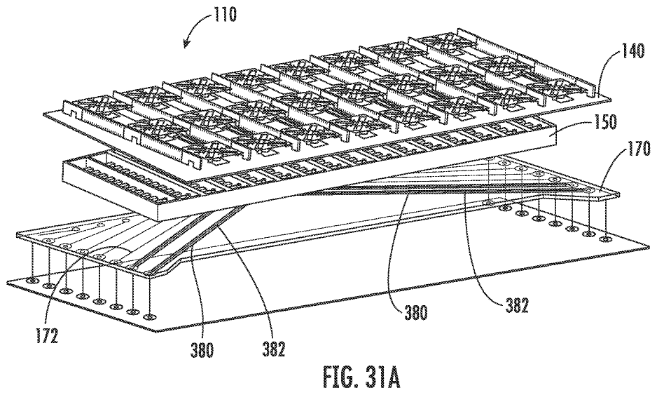

It is also noted that a coplanar grounded waveguide feature may be used with microstrip lines, such as those on the feed boards 140 and/or the adaptor board 170, e.g., signal traces/transmission lines 172, 254, 382 (see below, FIG. 31A), for example, to constrain/shield RF signal according to some embodiments.

It is noted that the feed boards 140 discussed above can be coupled together to substantially reside in a common plane. The term “substantially with respect to a common plane” means that slight variations may occur over a length and or width but that edge to edge, the feed boards 140 can reside within about +/−10 degrees of a primary plane of each other and/or of a primary plane of the radome 111 and/or adaptor board 170.

The feed boards 140 can be provided in any suitable number, typically in a range of 2-20, such as 4-8, in some embodiments. For example, where there are 8 cavity filters 150, the feed boards 140 can be provided as 4-8 feed boards and each feed board 140 can have 12-24 radiating elements 120 mounted thereon.

In some particular embodiments, the feed boards 140 and/or adaptor board 170 can be provided as multi-layer printed circuit boards that incorporate calibration circuitry.

The conductors 144 can extend through the feed boards 140 to provide the feed board connections and can be soldered to the respective feed boards 140. Each conductor 144 may comprise, for example, a metal pin or rod.

It is to be noted that in some embodiments, the conductors 144 can be configured as pogo pin contacts and do not require soldering for attachment/assembled connection thereby allowing for easier disassembly from the cavity filter 150. The conductors 144 may pass RF signals from the cavity filter 150 to the feed board(s) 140.

Each unit cavity filter 150u is associated with a corresponding feed board 140 in some embodiments. In some embodiments, each feed board 140 includes four columns of dual-polarized radiating elements 120, with three radiating elements 120 per column. In some embodiments, eight conductors 144 may be provided per cavity filter 150, so that two conductors 144 are coupled to each column of radiating elements, namely one conductor 144 for each polarization. Thus, the active antenna unit 110 may include a total of 64 inner conductors 144 in this example embodiment. Other numbers and arrangements may be used.

Turning now to FIGS. 19-22, an example coaxial cable assembly 280a with a coaxial cable 280 is shown. The coaxial cable assembly 280a may be mounted on the adaptor boards 170 according to embodiments of the present invention to implement longer electrical connections on the adaptor boards 170. This may be advantageous as coaxial cables have smaller insertion losses than microstrip traces, and hence implementing the longer electrical connection using coaxial cables may reduce insertion losses, and hence increase the gain of the antenna using the adaptor board 170.

As shown in FIGS. 19-22, the coaxial cable assembly 280a can comprise a support member 285 that can be configured to couple to a printed circuit board 288. The support member 285 can be metal. As shown, two support members 285 are used, one at each of axially spaced apart and opposing ends of the cable 280. The support member 285 can have an outer wall that is semi-circular and configured to hold a portion of the coaxial cable 280. The support member 285 has a first end portion 286 that extends in a first direction and a second end portion 287 that extends in a second direction that is orthogonal to the first direction. The 90-degree bend in the support member 285 can facilitate a strong mechanical support and soldering joint protection of the coaxial cable 280. The second end portion 287 can have a circular collar that surrounds the coaxial cable 280 thereat. Outwardly projecting tabs 288 can extend from the collar 287c. The center conductor 280c of the coaxial cable 280 can extend through an aperture 290a and terminate on an opposing side of the printed circuit board and the tabs 288 can extend through apertures 290a and reside on diametrically opposed sides of the center conductor 280c. Although shown as two tabs 288, three or four or more tabs 288 may be used (not shown).

Referring to FIG. 22, the support member 285 can define a head space or clearance “h” between the primary surface 290p of the printed circuit board 290 and the coaxial cable 285 so that the cable 280 is closely spaced apart from the surface 290p, typically a distance in a range 0.1-1.0 inches.

Turning now to FIGS. 23-27, another example coaxial cable assembly 280a′ is shown. The assembly 280′ comprises the coaxial cable 280 and at least one shielding cover 295. The shielding cover 295 can comprise or be formed of metal. The shielding cover 295 has an open end 295e that merges into a closed end 295c. The shielding cover 295 has a channel 298 that covers a portion of the coaxial cable 280. The center conductor 280c bends 90 degrees into an aperture 290a in the printed circuit board 290 and can be soldered on the other side (opposite the side with the shielding cover 295). The outer jacket 280j of the coaxial cable 280 can be removed adjacent and outside of open end 295e of the cover 295 so that only the dielectric insulator and the inner conductor, 280i, 280c, respectively, reside in the channel of the cover 295. The outer wall 299 of the cover 295 at the open end 295e and a major distance toward the closed end 295c can have a “U” shaped profile. Free ends 299f of the outer wall 299 can abut a primary surface of the printed circuit board 290. The coaxial cable 280 can lay on the ground side of the printed circuit board. The shielding cover 295 can provide RF shielding which can be particularly important for signal integrity at high frequency bands. FIGS. 25A-25C illustrate that the outer wall 299 of the shielding cover 295 can have other configurations. FIG. 25B illustrates planar feet 299f and FIG. 25C illustrates a planar bottom surface 299b that extends across and connects the opposing sides of the outer wall 299.

FIG. 31B shows that a coaxial cable 280, optionally the coaxial cable assembly 280a, 280a′ can be used for providing one or more signal path for the adaptor board 170 and may reduce RF path loss, particularly for longer signal traces 172l of radio transmission signal paths. That is, the printed circuit board 290 shown in FIG. 19 or FIG. 23 can be the adaptor board 170. However, the coaxial cable assembly 280a may be useful for other applications.

Turning now to FIGS. 28-30, a signal path assembly 300 is shown that comprises a strip printed circuit board 380 with at least one signal trace 382 coupled to a primary printed circuit board 290. The primary printed circuit board 290 can be the adaptor board 170 and the at least one signal trace 382 can provide a radio transmission signal path for an active antenna unit 110 as shown in FIG. 31A. The strip printed circuit board 380 can have a low dissipation factor (“DF”) material such as air or similar to air. The term “low DF” refers to materials having a DF< or = to 0.0010. The strip printed circuit board can be an elongate printed circuit board comprising at least one linear signal transmission path 382. The strip printed circuit board 380 has a width dimension and a length dimension and the length dimension can be at least five times larger than the width dimension, typically 5-20 times larger. The signal trace 382 can have a length of 3-15 inches.

In some embodiments, the primary printed circuit board 290 can have a DF that is in a range of about 0.0020~0.0030 and the strip printed circuit board 380 can have a DF that is <0.0010. The printed circuit boards 290, 380 can be laminated together.

The primary printed circuit board 290 can have a DF that is greater than that of the strip printed circuit board 380. The signal path can be defined by a first signal trace 382 on the strip printed circuit board 380 and second and third signal traces 292 on opposing ends of the first signal trace 382. The strip printed circuit board 380 can have first and second ground layers, 383, 385 separated by a dielectric layer 387 with the signal trace 382 in the dielectric layer 387 between the ground layers 383, 385. The primary printed circuit board 290 can have first and second ground layers 292, 295, separated by a dielectric layer 297. The signal trace 292 can reside in the dielectric layer 297. A conductive connector pin 390 can extend through aligned metallized apertures 380a, 290a in the strip and primary printed circuit boards 380, 290, electrically connecting the signal traces 382, 292. Soldering pads 389 can be used to affix the connector pin 390 in position. The strip printed circuit board can have a single signal trace 382 as shown, or a plurality of signal traces (not shown). When arranged as a plurality of traces 382, the traces 382 can be parallel and replace a subset of the adjacent signal traces 172 of the adaptor board 170 (such as two of the longer traces shown in FIG. 31A).

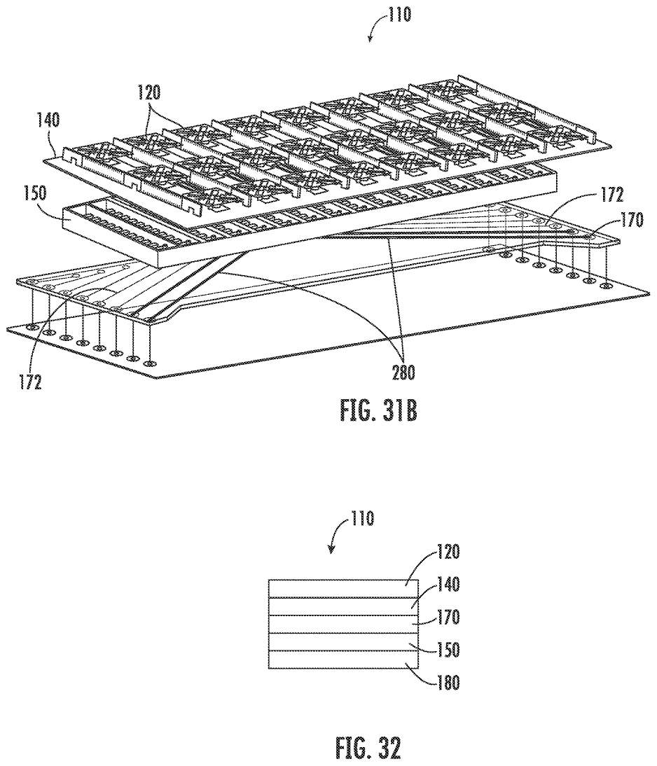

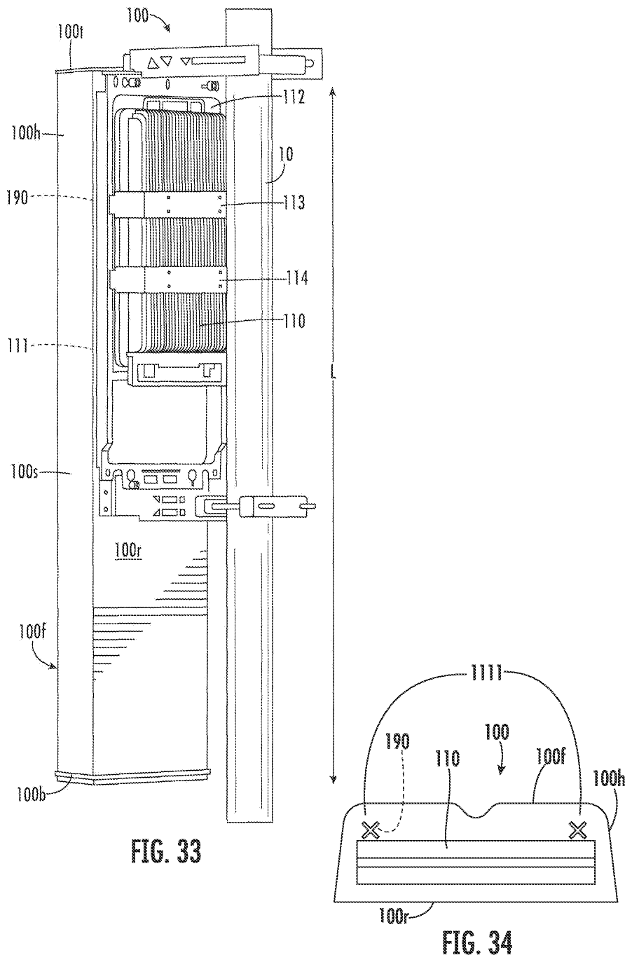

FIG. 32 illustrates that the adaptor board 170 can be positioned between the feed boards 140 and the cavity filters 150. The adaptor board 170 can comprise calibration circuitry.

The active antenna unit 110 with the radio 180 can be configured as a 5G module in some embodiments. With the introduction of fifth generation (“5G”) cellular technologies, base station antennas are now routinely being deployed that have active beamforming capabilities. Active beamforming refers to transmitting RF signals through a multi-column array of radiating elements in which the relative amplitudes and phases of the sub-components of an RF signal that are transmitted (or received) through the different radiating elements of the array are adjusted so that the radiation patterns that are formed by the individual radiating elements constructively combine in one or more desired directions to form narrower antenna beams that have higher gain. With active beamforming, the shape and pointing direction of the antenna beams generated by the multi-column array may, for example, be changed on a time slot-by-time slot basis of a time division duplex (“TDD”) multiple access scheme. Moreover, different antenna beams can be generated simultaneously on the same frequency resource in a multi-user MIMO scenario. More sophisticated active beamforming schemes can apply different beams to different physical resource blocks that are a combination of time and frequency resources by applying the beam vector in the digital domain. Base station antennas that have active beamforming capabilities are often referred to as active antennas. When the multi-column array includes a large number of columns of radiating elements (e.g., sixteen or more), the array is often referred to as a massive MIMO array. A module that includes a multi-column array of radiating elements and associated RF circuitry (and perhaps baseband circuitry) that implement an active antenna is referred to herein as an active antenna module.

Referring to FIG. 27, a base station antenna 100 according to some embodiments is shown. The base station antenna 100 includes a passive antenna assembly 190 with a plurality of internal linear arrays 1111 of radiating elements arranged in a plurality of laterally spaced apart and adjacent longitudinally extending columns between a top 100t and a bottom 100b of the base station antenna 100. In an example embodiment, there are eight columns of linear arrays 1111 of radiating elements.

The active antenna unit 110 can be held against a rear 100r of a housing 100h of the base station antenna 100 comprising the passive antenna assembly with a bracket assembly 112 having first and second laterally extending spaced apart brackets 113, 114. The housing 100h has a front surface 100f defining a radome and sides 100s and a rear 100r. The bracket assembly 112 can also mount the base station antenna housing 100h with the active antenna unit 110 to a target structure such as a pole 10.

FIG. 28 illustrates another embodiment of a base station antenna 100 with a housing comprising a passive antenna assembly 190 sized and configured to hold the active antenna unit 110 at least partially internally thereof.

The base station antenna 100 can include one or more arrays of low-band radiating elements, one or more arrays of mid-band radiating elements, and one or more arrays of high-band radiating elements. The radiating elements may each be dual-polarized radiating elements. Further details of radiating elements can be found in co-pending WO 2019/236203 and WO 2020/072880, the contents of which are hereby incorporated by reference as if recited in full herein. For further details regarding example active antenna modules and base station antenna housings with passive antenna assemblies, see, co-pending U.S. patent application Ser. No. 17/209,562 and corresponding PCT Patent Application Serial Number PCT/US2021/023617, the contents of which are hereby incorporated by reference as if recited in full herein.

The linear arrays of the active antenna unit 110 and/or 1111 of the passive antenna assembly 190, can be provided as low, mid or high band radiating element. Typically, the linear arrays will include mid-band or high-band radiating elements. When high-band radiating elements are used, they may be configured to transmit and receive signals in a first frequency band. In some embodiments, the first frequency band may be the 3.3-4.2 GHz frequency band or a portion thereof. In other embodiments, the first frequency band may be the 5.1-5.8 GHz frequency band or a portion thereof. When mid-band radiating elements are used, the first frequency band may be, for example, the 1.695-2.690 GHz frequency band or a portion thereof.

It will be appreciated that other types of radiating elements may be used, that more or fewer linear arrays may be included in the antenna, that the number of radiating elements per array may be varied, and that planar arrays or staggered linear arrays may be used instead of the “straight” linear arrays illustrated in the figures in other embodiments.

Embodiments of the present invention have been described above with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout.

In the discussion above, reference is made to the linear arrays of radiating elements that are commonly included in base station antennas. It will be appreciated that herein the term “linear array” is used broadly to encompass both arrays of radiating elements that include a single column of radiating elements that are configured to transmit the sub-components of an RF signal as well as to two-dimensional arrays of radiating elements (i.e., multiple linear arrays) that are configured to transmit the sub-components of an RF signal. It will also be appreciated that in some cases the radiating elements may not be disposed along a single line. For example, in some cases a linear array of radiating elements may include one or more radiating elements that are offset from a line along which the remainder of the radiating elements are aligned. This “staggering” of the radiating elements may be done to design the array to have a desired azimuth beamwidth. Such staggered arrays of radiating elements that are configured to transmit the sub-components of an RF signal are encompassed by the term “linear array” as used herein.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element is referred to as being “on” another element, it can be directly on the other element or intervening elements may also be present. In contrast, when an element is referred to as being “directly on” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (i.e., “between” versus “directly between”, “adjacent” versus “directly adjacent”, etc.).

The term “about” with respect to a number, means that the stated number can vary by +/−20%.

Relative terms such as “below” or “above” or “upper” or “lower” or “horizontal” or “vertical” may be used herein to describe a relationship of one element, layer or region to another element, layer or region as illustrated in the figures. It will be understood that these terms are intended to encompass different orientations of the device in addition to the orientation depicted in the figures.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” “comprising,” “includes” and/or “including” when used herein, specify the presence of stated features, operations, elements, and/or components, but do not preclude the presence or addition of one or more other features, operations, elements, components, and/or groups thereof.

Aspects and elements of all of the embodiments disclosed above can be combined in any way and/or combination with aspects or elements of other embodiments to provide a plurality of additional embodiments.

1. An active antenna unit, comprising:
a radio with a plurality of radio ports; and
an adaptor board comprising a plurality of radio frequency (RF) ports that communicate with the radio ports and signal traces that connect the RF ports to other ports of the active antenna unit.

2. The active antenna unit of claim 1, wherein the signal traces connect the RF ports to respective filter cavity ports.

3. The active antenna unit of claim 1, wherein some of the signal traces are longer than others of the signal traces.

4. The active antenna unit of claim 1, wherein the RF ports are aligned in a vertical or horizontal direction.

5. The active antenna unit of claim 1, wherein the RF ports are laterally staggered and arranged to serially alter over a length of the adaptor board between a first lateral position and a second lateral position.

6. The active antenna unit of claim 1, wherein at least some of the signal traces are angled laterally across the adaptor board, parallel to each other.

7. The active antenna unit of claim 1, further comprising at least one coaxial cable extending along and/or across the adaptor board between first and second ports corresponding to one of the RF ports and one of the other ports of the active antenna unit.

8. The active antenna unit of claim 1, wherein the adaptor board comprises a primary printed circuit board and a strip printed circuit board coupled to the primary printed circuit board, wherein the primary printed circuit board has a larger surface area than the strip printed circuit board, and wherein the strip printed circuit board comprises a signal trace.

9. The active antenna unit of claim 8, wherein the strip printed circuit board comprises a dielectric substrate having a lower dielectric constant material than a dielectric substrate of the primary printed circuit board.

10. The active antenna unit of claim 1, wherein a first subset of the RF ports are connected to feed boards of radiating elements of the active antenna unit.

11. The active antenna unit of claim 1, wherein the adaptor board comprises a strip printed circuit board with at least one signal trace thereon that is configured to angle laterally across a length dimension of the adaptor board.

12. The active antenna unit of claim 8, wherein the signal trace of the one or more strip printed circuit boards connects to an aligned signal trace on the adaptor board.

13. The active antenna unit of claim 1, further comprising cavity filters residing behind feed boards of radiating elements of the active antenna unit, wherein the adaptor board defines a front cover for the radio and also defines a rear cover for the cavity filters.

14. The active antenna unit of claim 13, wherein the adaptor board is attached to the cavity filters.

15. The active antenna unit of claim 1, further comprising a module sub-assembly comprising cavity filters, each cavity filter having a respective cavity filter unit housing, and feed boards coupled to radiating elements residing in front of the cavity filter housing.

16. The active antenna unit of claim 15, wherein the adaptor board is provided as a plurality of different adaptor boards, each with a different signal trace configuration and different radio port locations and a common footprint, and wherein each of the plurality of different adaptor boards is interchangeably, serially attachable to the active antenna unit to thereby allow the active antenna unit to connect and interface with different radios with different radio port configurations.

17. The active antenna unit of claim 1, further comprising cavity filters coupled to the adaptor board, wherein the adaptor board comprises tuning elements configured to tune the cavity filters.

18. The active antenna unit of claim 1, wherein the adaptor board is arranged to define a low pass filter function.

19. The active antenna unit of claim 1, further comprising cavity filters with twistable tuning elements, wherein the adaptor board comprises a sheet metal layer that is coupled to a ground plane side of the adaptor board and that extends over at least one access aperture of respective cavity filters and over at least one twistable tuning element in each of the respective cavity filters.

20. The active antenna unit of claim 1, further comprising a radome mounted forwardly of a radio housing holding the radio and a plurality of feed boards with a plurality of radiating elements projecting forward of the plurality of feed boards residing between the adaptor board and the radome.

21. The active antenna unit of claim 20, wherein the plurality of radiating elements comprise a massive multiple input multiple output (MIMO) antenna array.

22. An assembly for an active antenna unit, comprising:
a radio board coupled to radio circuitry of a radio;
an adaptor board coupled to the radio board and comprising a plurality of spaced apart apertures; and
a cavity filter assembly coupled to the adaptor board and comprising a plurality of cavity filters with a respective tuning element in a respective cavity thereof, wherein at least one aperture of the spaced apart apertures of the adaptor board resides behind and over each cavity of the cavity filters whereby capacitance of the tuning element is adjustable through the at least one aperture.

23-27. (canceled)

28-34. (canceled)

35. An adaptor board assembly, comprising:
a first printed circuit board comprising a dielectric layer and first and second electrical ground layers on opposing sides of the dielectric layer, wherein the first printed circuit board has a width and length dimension, and wherein the first printed circuit board comprises a signal trace in the dielectric layer that extends along the length dimension and that extends only along outer facing ends of the first printed circuit board from a soldering pad; and
a second printed circuit board comprising a dielectric layer and first and second electrical ground layers on opposing sides of the dielectric layer, wherein the second printed circuit board has a width and length dimension, wherein the second printed circuit board comprises a signal trace in the dielectric layer that extends along the length dimension and terminates at a soldering pad aligned with the soldering pad of the first printed circuit board, wherein at least one of the width and length dimension of the second printed circuit board is less than that of the first printed circuit board, wherein the second printed circuit board is coupled to the first printed circuit board, and wherein the signal trace of the second printed circuit board has a longer extent than the signal trace of the first printed circuit board to thereby provide a low loss signal path.

36-40. (canceled)
